(19) United States
(12) Patent Application Publication
(10) Pub. No.: US 2026/0155836 A1
(43) Pub. Date: Jun. 4, 2026

(54) LEARNING-BASED MIN-SUM HARD DECODING FOR NON-VOLATILE MEMORY DEVICES

(71) Applicant: SK hynix Inc., Icheon-si (KR)

(72) Inventors: Pengfei Huang, San Jose, CA (US); Fan Zhang, Fremont, CA (US); Hongwei Duan, Cupertino, CA (US)

(21) Appl. No.: 18/964,593

(22) Filed: Dec. 1, 2024

(51) Int. Cl. H03M 13/11; H03M 13/09

(52) U.S. Cl. CPC H03M 13/1125; H03M 13/096; H03M 13/1128

(57) ABSTRACT

Methods and systems for improving performance of a decoder in a memory device are described. An example method includes receiving a noisy codeword, generating, based on the noisy codeword, a first log likelihood ratio (LLR) sequence that uses symmetric LLR metrics, and performing, on a second LLR sequence, a decoding iteration to generate a decoded data sequence. Upon determining that a checksum of the decoded data sequence satisfies a condition, the method further includes generating, based on the decoded data sequence, an intermediate sequence, incrementing at least one of multiple counters based on comparing corresponding bits of the intermediate sequence and the noisy codeword, and updating, based on the multiple counters, the second LLR sequence, which is used to perform another decoding iteration. An example system implements the above-described method using one or more processors.

### TECHNICAL FIELD

This patent document generally relates to memory devices with error-correcting codes, and more specifically, to improving the performance of low-density parity-check (LDPC) codes used in memory devices.

### BACKGROUND

Error-correcting code (ECC) memory is a type of computer data storage that can detect and correct the most common kinds of internal data corruption. ECC memory is primarily used in servers and workstations where data integrity is crucial. It works by adding extra bits to each data word, which are used to check and correct errors. This ensures that data read from memory is always accurate, even if a bit has been flipped due to electrical interference or other issues. ECC memory is essential for applications requiring high reliability and stability, such as financial systems, scientific computing, and mission-critical databases. Thus, there remains the need for robust ECC memory that can meet increased quality-of-service (QoS) requirements.

### SUMMARY

Embodiments of the disclosed technology relate to methods, systems, and devices that improve performance of a low-density parity check (LDPC) code in a memory device. In an example, the performance of the memory device is improved by adapting the log-likelihood ratio (LLR) during each iteration of the min-sum hard (MSH) decoding of the LDPC code, and based on learning the underlying hard read channel. The improved decoder shows improved correction capabilities and reduced decoding latencies, thereby increasing the quality-of-service (QoS) of the memory device, e.g., a quad-level cell (QLC)-based memory device.

In one example, a method for improving performance of a memory device is described. The method includes (a) receiving, from at least one memory cell of the memory device, a noisy codeword that is based on a transmitted codeword generated from a low-density parity-check (LDPC) code, (b) generating, based on the noisy codeword, a first log likelihood ratio (LLR) sequence that uses symmetric LLR metrics, and (c) performing, on a second LLR sequence, a decoding iteration to generate a decoded data sequence, wherein the second LLR sequence is based on the first LLR sequence. Upon determining that a checksum of the decoded data sequence satisfies a condition indicative of the noisy codeword not being successfully decoded, the method further includes (d) generating, based on the decoded data sequence, an intermediate sequence, (e) incrementing at least one of a first counter (B_00), a second counter (B_01), a third counter (B_10), or a fourth counter (B_11) based on comparing corresponding bits of the intermediate sequence and the noisy codeword, and (f) updating, based on the first counter, the second counter, the third counter, and the fourth counter, the second LLR sequence. The method further includes repeating operations (c) through (f) until the noisy codeword is successfully decoded or an index of the decoding iteration has exceeded a maximum number of decoding iterations.

In another example, the methods may be embodied in the form of an apparatus that includes a processor and a memory coupled to the processor.

In yet another example, the methods may be embodied in the form of processor-executable instructions and stored on a computer-readable program medium.

The subject matter described in this patent document can be implemented in specific ways that provide one or more of the following features.

### BRIEF DESCRIPTION OF THE DRAWINGS

FIG. 1 illustrates an example of a memory system.

FIG. 2 is an illustration of an example non-volatile memory device.

FIG. 3 is an example diagram illustrating the cell voltage level distribution (Vth) of a non-volatile memory device.

FIG. 4 is another example diagram illustrating the cell voltage level distribution (Vth) of a non-volatile memory device.

FIG. 5 is an example diagram illustrating the cell voltage level distribution (Vth) of a non-volatile memory device before and after program interference.

FIG. 6 is an example diagram illustrating the cell voltage level distribution (Vth) of a non-volatile memory device as a function of the reference voltage.

FIG. 7 is an example diagram illustrating the architecture of a system that implements a learning-based min-sum hard (MSH) decoder.

FIG. 8 is an example diagram illustrating the architecture of another system that implements a learning-based min-sum hard (MSH) decoder.

FIG. 9 is an example diagram illustrating a log-likelihood ratio (LLR) update circuit.

FIG. 10 is an example diagram illustrating a storage device that can be configured to implement the described embodiments.

FIG. 11 illustrates a flowchart of an example method for improving the performance of a decoder in a memory device.

### DETAILED DESCRIPTION

Semiconductor memory devices may be volatile or nonvolatile. The volatile semiconductor memory devices perform read and write operations at high speeds, while contents stored therein may be lost at power-off. The nonvolatile semiconductor memory devices may retain contents stored therein even at power-off. The nonvolatile semiconductor memory devices may be used to store contents, which must be retained regardless of whether they are powered.

With an increase in a need for a large-capacity memory device, a multi-level cell (MLC) or multi-bit memory device storing multi-bit data per cell is becoming more common. However, memory cells in an MLC non-volatile memory device must have threshold voltages corresponding to four or more discriminable data states in a limited voltage window. For improvement of data integrity in non-volatile memory devices, the levels, and distributions of read voltages for discriminating the data states must be adjusted over the lifetime of the memory device to have optimal values during read operations and/or read attempts.

Section headings are used in the present document to improve readability of the description and do not in any way limit the discussion or the embodiments (and/or implementations) to the respective sections only.

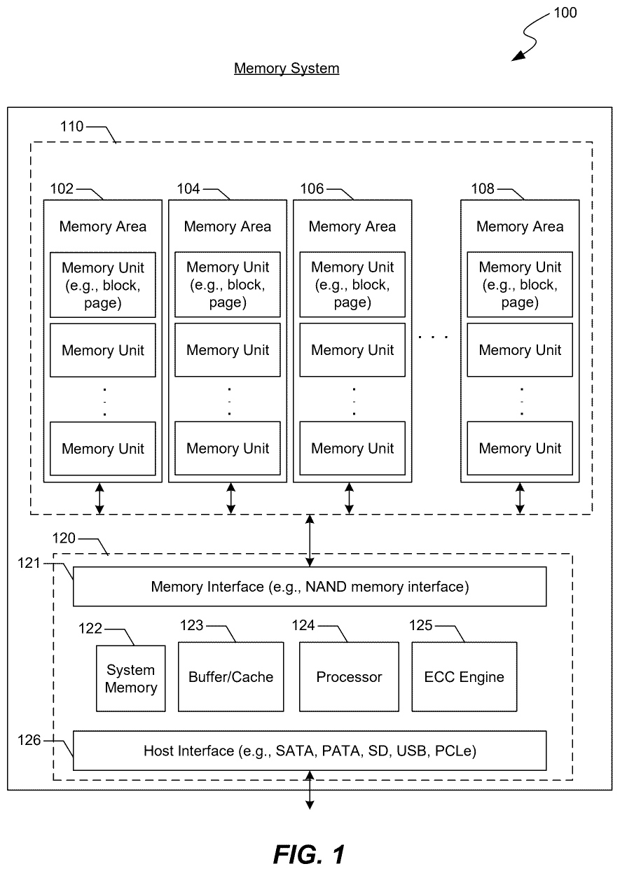

FIGS. 1-6 overview a non-volatile memory system (e.g., a flash-based memory, NAND flash) in which embodiments of the disclosed technology may be implemented.

FIG. 1 is a block diagram of an example of a memory system 100 implemented based on some embodiments of the disclosed technology. The memory system 100 includes a memory module 110 that can be used to store information for use by other electronic devices or systems. The memory system 100 can be incorporated (e.g., located on a circuit board) in other electronic devices and systems. Alternatively, the memory system 100 can be implemented as an external storage device such as a USB flash drive and a solid-state drive (SSD).

The memory module 110 included in the memory system 100 can include memory areas (e.g., memory arrays) 102, 104, 106, and 108. Each of the memory areas 102, 104, 106, and 108 can be included in a single memory die or in multiple memory dice. The memory die can be included in an integrated circuit (IC) chip.

Each of the memory areas 102, 104, 106, and 108 includes a plurality of memory cells. Read, program, or erase operations can be performed on a memory unit basis. Thus, each memory unit can include a predetermined number of memory cells. The memory cells in a memory area 102, 104, 106, and 108 can be included in a single memory die or in multiple memory dice.

The memory cells in each of memory areas 102, 104, 106, and 108 can be arranged in rows and columns in the memory units. Each of the memory units can be a physical unit. For example, a group of a plurality of memory cells can form a memory unit. Each of the memory units can also be a logical unit. For example, the memory unit can be a block or a page that can be identified by a unique address such as a block address or a page address, respectively. For another example, wherein the memory areas 102, 104, 106, and 108 can include computer memories that include memory banks as a logical unit of data storage, the memory unit can be a bank that can be identified by a bank address. During a read or write operation, the unique address associated with a particular memory unit can be used to access that particular memory unit. Based on the unique address, information can be written to or retrieved from one or more memory cells in that particular memory unit.

The memory cells in the memory areas 102, 104, 106, and 108 can include non-volatile memory cells. Examples of non-volatile memory cells include flash memory cells, phase change random-access memory (PRAM) cells, magnetoresistive random-access memory (MRAM) cells, or other types of non-volatile memory cells. In an example implementation where the memory cells are configured as NAND flash memory cells, the read or write operation can be performed on a page basis. However, an erase operation in a NAND flash memory is performed on a block basis.

Each of the non-volatile memory cells can be configured as a single-level cell (SLC) or multiple-level memory cell. A single-level cell can store one bit of information per cell. A multiple-level memory cell can store more than one bit of information per cell. For example, each of the memory cells in the memory areas 102, 104, 106, and 108 can be configured as a multi-level cell (MLC) to store two bits of information per cell, a triple-level cell (TLC) to store three bits of information per cell, or a quad-level cells (QLC) to store four bits of information per cell. In another example, each of the memory cells in memory area 102, 104, 106, and 108 can be configured to store at least one bit of information (e.g., one bit of information or multiple bits of information), and each of the memory cells in memory area 102, 104, 106, and 108 can be configured to store more than one bit of information.

As shown in FIG. 1, the memory system 100 includes a controller module 120. The controller module 120 includes a memory interface 121 to communicate with the memory module 110, a host interface 126 to communicate with a host (not shown), a processor 124 to execute firmware-level code, and caches and memories 123 and 122, respectively to temporarily or persistently store executable firmware/instructions and associated information. In some implementations, the controller unit 120 can include an error correction engine 125 to perform error correction operation on information stored in the memory module 110. Error correction engine 125 can be configured to detect/correct single bit error or multiple bit errors. In another implementation, error correction engine 125 can be located in the memory module 110.

The host can be a device or a system that includes one or more processors that operate to retrieve data from the memory system 100 or store or write data into the memory system 100. In some implementations, examples of the host can include a personal computer (PC), a portable digital device, a digital camera, a digital multimedia player, a television, and a wireless communication device.

In some implementations, the controller module 120 can also include a host interface 126 to communicate with the host. Host interface 126 can include components that comply with at least one of host interface specifications, including but not limited to, Serial Advanced Technology Attachment (SATA), Serial Attached Small Computer System Interface (SAS) specification, Peripheral Component Interconnect Express (PCIe).

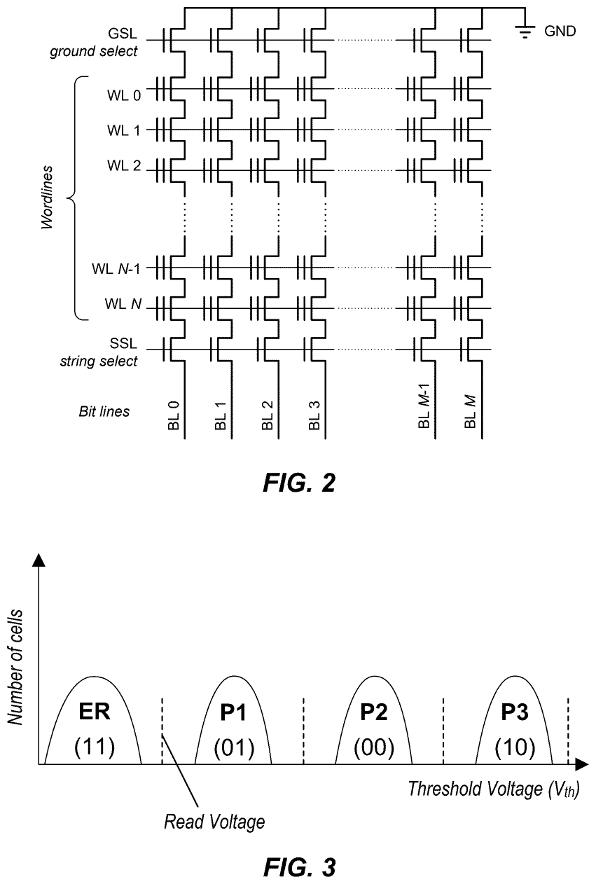

FIG. 2 illustrates an example of a memory cell array implemented based on some embodiments of the disclosed technology.

In some implementations, the memory cell array can include NAND flash memory array that is partitioned into many blocks, and each block contains a certain number of pages. Each block includes a plurality of memory cell strings, and each memory cell string includes a plurality of memory cells.

In some implementations where the memory cell array is NAND flash memory array, read and write (program) operations are performed on a page basis, and erase operations are performed on a block basis. All the memory cells within the same block must be erased at the same time before performing a program operation on any page included in the block. In an implementation, NAND flash memories may use an even/odd bit-line structure. In another implementation, NAND flash memories may use an all-bit-line structure. In the even/odd bit-line structure, even and odd bit-lines are interleaved along each word-line and are alternatively accessed so that each pair of even and odd bit-lines can share peripheral circuits such as page buffers. In all-bit-line structure, all the bit-lines are accessed at the same time.

FIG. 3 illustrates an example of threshold voltage distribution curves in a multi-level cell device, wherein the number of cells for each program/erase state is plotted as a function of the threshold voltage. As illustrated therein, the threshold voltage distribution curves include the erase state (denoted “ER” and corresponding to “11”) with the lowest threshold voltage, and three program states (denoted “P1”, “P2” and “P3” corresponding to “01”, “00” and “10”, respectively) with read voltages in between the states (denoted by the dotted lines). In some embodiments, each of the threshold voltage distributions of program/erase states has a finite width because of differences in material properties across the memory array.

Although FIG. 3 shows a multi-level cell device by way of example, each of the memory cells can be configured to store any number of bits per cell. In some implementations, each of the memory cells can be configured as a single-level cell (SLC) to store one bit of information per cell, or as a triple-level cell (TLC) to store three bits of information per cell, or as a quad-level cells (QLC) to store four bits of information per cell.

In writing more than one data bit in a memory cell, fine placement of the threshold voltage levels of memory cells is needed because of the reduced distance between adjacent distributions. This is achieved by using incremental step pulse program (ISPP), i.e., memory cells on the same word-line are repeatedly programmed using a program-and-verify approach with a staircase program voltage applied to word-lines. Each programmed state associates with a verify voltage that is used in verify operations and sets the target position of each threshold voltage distribution window.

Read errors can be caused by distorted or overlapped threshold voltage distribution. An ideal memory cell threshold voltage distribution can be significantly distorted or overlapped due to, e.g., program and erase (P/E) cycle, cell-to-cell interference, and data retention errors, which will be discussed in the following, and such read errors may be managed in most situations by using an error correction code (ECC).

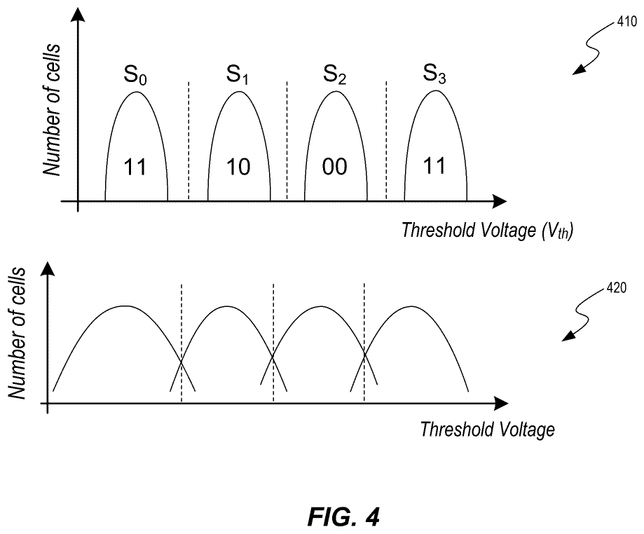

FIG. 4 illustrates an example of ideal threshold voltage distribution curves 410 and an example of distorted threshold voltage distribution curves 420. The vertical axis indicates the number of memory cells that have the threshold voltage represented on the horizontal axis.

For n-bit multi-level cell NAND flash memory, the threshold voltage of each cell can be programmed to 2ⁿ possible values. In an ideal multi-level cell NAND flash memory, each value corresponds to a non-overlapping threshold voltage window.

Flash memory P/E cycling causes damage to a tunnel oxide of floating gate of a charge trapping layer of cell transistors, which results in threshold voltage shift and thus gradually degrades memory device noise margin. As P/E cycles increase, the margin between neighboring distributions of different programmed states decreases and eventually the distributions start overlapping. The data bit stored in a memory cell with a threshold voltage programmed in the overlapping range of the neighboring distributions may be misjudged as a value other than the original targeted value.

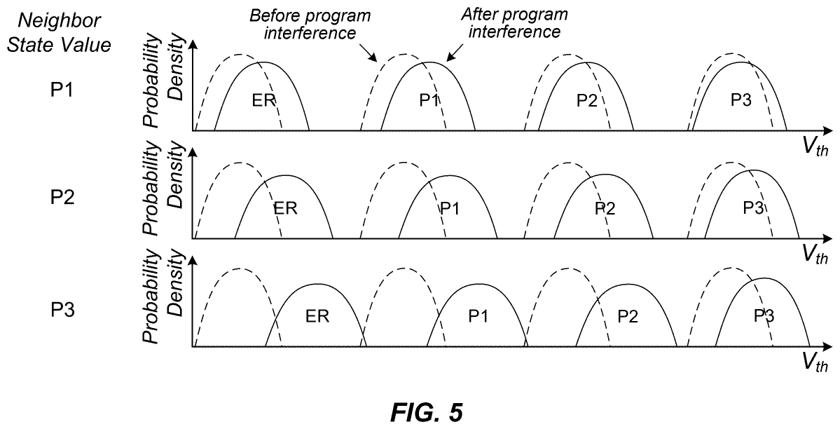

FIG. 5 illustrates an example of a cell-to-cell interference in NAND flash memory. The cell-to-cell interference can also cause threshold voltages of flash cells to be distorted. The threshold voltage shift of one memory cell transistor can influence the threshold voltage of its adjacent memory cell transistor through parasitic capacitance-coupling effect between the interfering cell and the victim cell. The amount of the cell-to-cell interference may be affected by NAND flash memory bit-line structure. In the even/odd bit-line structure, memory cells on one word-line are alternatively connected to even and odd bit-lines and even cells are programmed ahead of odd cells in the same word-line. Therefore, even cells and odd cells experience different amount of cell-to-cell interference. Cells in all-bit-line structure suffer less cell-to-cell interference than even cells in the even/odd bit-line structure, and the all-bit-line structure can effectively support high-speed current sensing to improve the memory read and verify speed.

The dotted lines in FIG. 5 denote the nominal distributions of P/E states (before program interference) of the cells under consideration, and the “neighbor state value” denotes the value that the neighboring state has been programmed to. As illustrated in FIG. 5, if the neighboring state is programmed to P1, the threshold voltage distributions of the cells under consideration shift by a specific amount. However, if the neighboring state is programmed to P2, which has a higher threshold voltage than P1, that results in a greater shift compared to the neighboring state being P1. Similarly, the shift in the threshold voltage distributions is greatest when the neighboring state is programmed to P3.

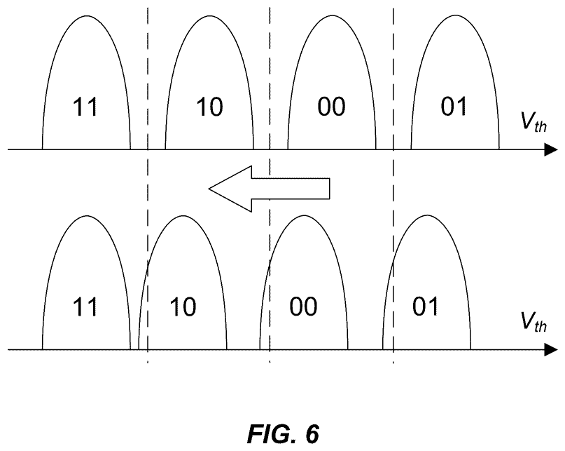

FIG. 6 illustrates an example of a retention error in NAND flash memory by comparing normal threshold-voltage distribution and shifted threshold-voltage distribution. The data stored in NAND flash memories tend to get corrupted over time and this is known as a data retention error. Retention errors are caused by loss of charge stored in the floating gate or charge trap layer of the cell transistor. Due to wear of the floating gate or charge trap layer, memory cells with more program erase cycles are more likely to experience retention errors. In the example of FIG. 6, comparing the top row of voltage distributions (before corruption) and the bottom row of distributions (contaminated by retention error) reveals a shift to the left.

In NAND-based storage systems (e.g., the examples illustrated in FIGS. 1-6) and solid-state drive (SSD) applications, the first read and a few subsequent read retries (or re-reads) depend on the min-sum hard (MSH) decoding capability. Herein, the log-likelihood ratio (LLR) plays one of the key roles in the correction capability and decoding latency of MSH decoder. During execution and use of the SSD, the initial fixed LLR of the MSH decoder is very likely no longer optimal because the read levels and NAND voltage distributions vary as a function of time. Thus, to leverage the optimal correction capabilities of an MSH decoder, embodiments of the disclosed technology adapt the LLR as a function of the underlying NAND channel.

The described embodiments relate to ECC architectures that automatically adapt the LLR during the MSH decoding. In some examples, this is achieved by learning the underlying hard read channel to adjust the LLR in each MSH decoding iteration, which results in the LLR eventually converging to the optimal LLR for the underlying NAND channel. Furthermore, the described embodiments are well-suited for low-complexity hardware implementations, and are compatible with existing ECC system-on-chip (SoC) designs. Numerical simulations evince that the described ECC engines can adjust the LLR successfully even in a very asymmetric channel, which can significantly improve the correction capability and reduce the decoding latency. In some examples, the disclosed embodiments advantageously improve the quality-of-service (QoS) of enterprise SSD products significantly, and in particularly, the quad-level cell (QLC)-based high capacity SSDs.

In some embodiments, and for an LDPC code with m×n parity-check matrix H, the checksum (CS) computation of a length-n noisy codeword r is determined by first computing:

$$SYND = {rH}^{T} .$$

Herein, the T subscript represents the transpose operation, and the checksum (CS) is the number of ones in SYND. In other embodiments, for an LDPC code with m×n parity-check matrix H which has a sub-matrix Hₛ, the partial checksum (PCS) computation of a length-n noisy codeword r can be determined by first computing SYND=rHₛ^{T}, with the PCS being the number of ones in the vector SYND. In some examples, the sub-matrix is the circulant matrix associated with one or more check nodes of the bipartite graph of the LDPC code.

In these embodiments, the LLRs of the hard read channel are determined as:

$$LLR ( 1 ) = log ( \frac{( p ( y = 1 \vert x = 0 )}{( p ( y = 1 \vert x = 1 )} )$$

$$LLR ( 0 ) = log ( \frac{( p ( y = 0 \vert x = 0 )}{( p ( y = 0 \vert x = 1 )} )$$

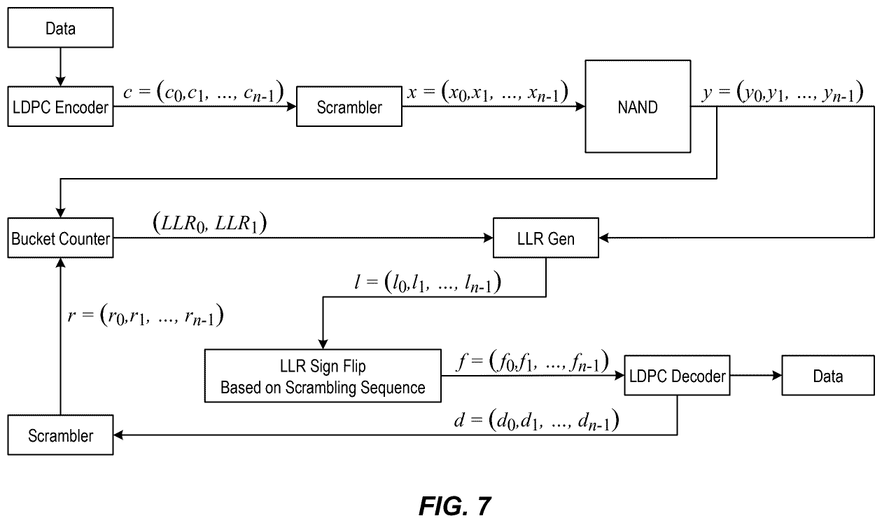

In some embodiments, and as shown in the example architecture in FIG. 7, the data is encoded by an LDPC encoder to generate a codeword c=(c₀, c₁, . . . , cₙ₋₁), which is input to a scrambler that generates a sequence x=(x₀, x₁, . . . , xₙ₋₁). Herein, x=bitwise_xor(c, s), where s=(s₀, s₁, . . . , sₙ₋₁) is a scrambling sequence associated with the scrambler.

In the decoding process shown in FIG. 7, multiple bucket counters (and more generally, multiple counters that can count bit errors between two bit vectors) are used to learn the underlying channel. As the decoding progresses, the estimation of the LLR becomes increasingly accurate. Pseudocode for the decoding process implemented in the architecture illustrated in FIG. 7 is shown below.
Step 1. Read raw data, y=(y₀, y₁, . . . , yₙ₋₁), from NAND.
Step 2. Initialize LLR0=4 and LLR1=−4.
Step 3. Generate an LLR sequence l=(l₀, l₁, . . . , lₙ₋₁) by applying LLR0 and LLR1 to y as follows:

```
for i = 0 : n−1
  if y_i == 0: l_i = LLR0
  else l_i = LLR1
  end
end
```

Step 4. Generate a flipped LLR sequence f=(f₀, f₁, . . . , fₙ₋₁) as follows:

```
for i = 0 : n−1
  if (scrambling seq bit) s_i == 1 : f_i = -l_i
  else f_i = l_i
  end
end
```

Step 5. Iteration loop till maximum number of iterations
   a. Perform min-sum hard decoding with LLR sequence (f₀, f₁, . . . , fₙ₋₁).
   b. If the checksum satisfies a condition
      Generate a sequence r=(r₀, r₁, . . . , rₙ₋₁) based on decoded data d=(d₀, d₁, . . . , dₙ₋₁), where r=bitwise_xor(d, s) and s is the scrambling sequence.
      Calculate bucket counters B_00, B_01, B_10 and B_11
      Generate LLR0 and LLR1
      Update the LLR sequence l=(l₀, l₁, . . . , lₙ₋₁) as in Step 3
      Update the flipped LLR sequence f=(f₀, f₁, . . . , fₙ₋₁) as in Step 4
   END (checksum satisfying condition)
END (iteration loop)

In Step 5b above, the bucket counters are calculated (for i=0, . . . , n−1) as follows:
B_00 is the number of positions in sequences r and y such that rᵢ=0 and yᵢ=0
B_01 is the number of positions in sequences r and y such that rᵢ=0 and yᵢ=1
B_10 is the number of positions in sequences r and y such that rᵢ=1 and yᵢ=0
B_11 is the number of positions in sequences r and y such that rᵢ=1 and yᵢ=1

In Step 5b above, LLR0 and LLR1 are generated as follows:

$$LLR 0 = round ( log ( \frac{B\_ 00}{B\_ 10} ) )$$

$$and$$

$$LLR 1 = round ( log ( \frac{B\_ 01}{B\_ 11} ) ) .$$

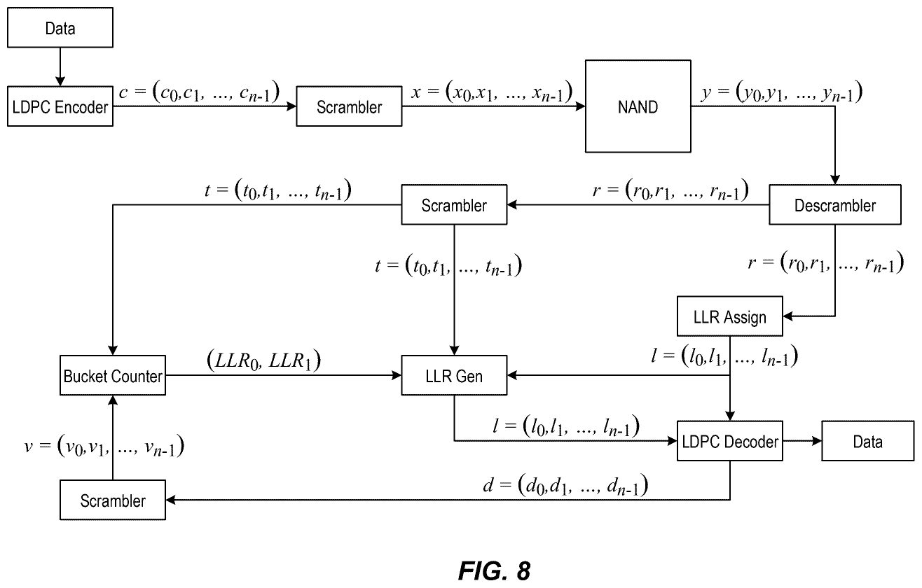

In some embodiments, and as shown in the example architecture in FIG. 8, the data is encoded by an LDPC encoder to generate a codeword c=(c₀, c₁, . . . , cₙ₋₁), which is input to a scrambler that generates a sequence x=(x₀, x₁, . . . , xₙ₋₁). Herein, x=bitwise_xor(c, s), where s=(s₀, s₁, . . . , sₙ₋₁) is a scrambling sequence associated with the scrambler. Pseudocode for the decoding process implemented in the architecture illustrated in FIG. 8 is shown below.
Step 1. Read raw data, y=(y₀, y₁, . . . , yₙ₋₁), from NAND.
Step 2. Generate a descrambled sequence r=(r₀, r₁, . . . , rₙ₋₁), where r=bitwise_xor(y, s) and s is the scrambling sequence.
Step 3. Initialize LLR0=4 and LLR1=−4.
Step 4. Generate an LLR sequence l=(l₀, l₁, . . . , lₙ₋₁) by applying LLR0 and LLR1 to r as follows:

```
for i = 0 : n−1
  if r_i == 0: l_i = LLR0
  else l_i = LLR1
  end
end
```

Step 5. Generate a sequence t=(t₀, t₁, . . . , tₙ₋₁), where t=bitwise_xor(r, s).
Step 6. Iteration loop till maximum number of iterations
   a. Perform min-sum hard decoding with LLR sequence (l₀, l₁, . . . , lₙ₋₁).
   b. If the checksum satisfies a condition
      Generate a sequence v=(v₀, v₁, . . . , vₙ₋₁) based on decoded data d=(do, d₁, . . . , dₙ₋₁), where v=bitwise_xor(d, s) and s is the scrambling sequence.
      Calculate bucket counters B_00, B_01, B_10 and B_11
      Generate LLR0 and LLR1
      Update the LLR sequence l=(l₀, l₁, . . . , lₙ₋₁) based on LLR0 and LLR1 computed above and the sequence t, as follows:

```
for i = 0 : n−1
  sign(l_i) = sign(l_i)
  if t_i == 0: mag(l_i) = mag(LLR0)
  else mag(l_i) = mag(LLR1)
  end
end
```

END (checksum satisfying condition)
END (iteration loop)

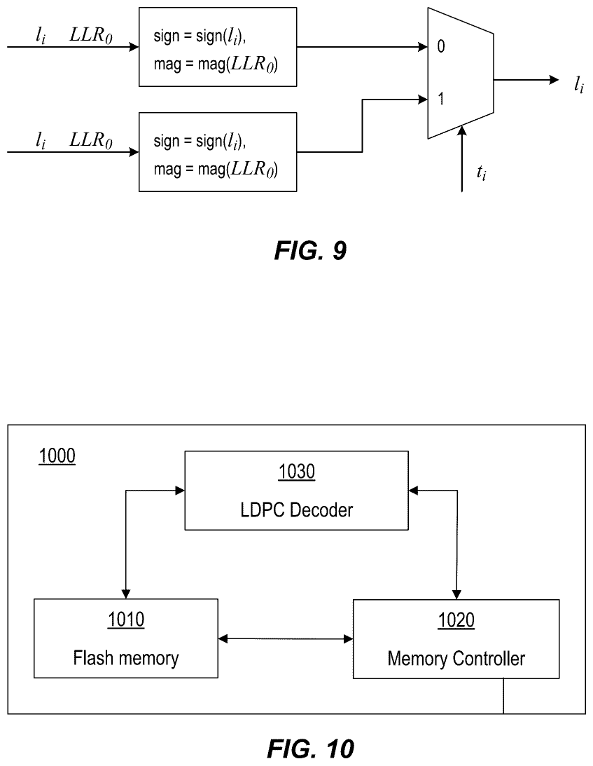

In Step 6b above, for updating the LLR sequence, the sign(·) and mag(·) functions return the sign and the magnitude of the input argument, respectively. Furthermore, updating the LLR sequence can be implemented using the LLR update circuit shown in FIG. 9.

In Step 6b above, the bucket counters are calculated (for i=0, . . . , n−1) as follows:
B_00 is the number of positions in sequences v and t such that vᵢ=0 and tᵢ=0
B_01 is the number of positions in sequences v and t such that vᵢ=0 and tᵢ=1
B_10 is the number of positions in sequences v and t such that vᵢ=1 and tᵢ=0
B_11 is the number of positions in sequences v and t such that vᵢ=1 and tᵢ=1

In the example implementation described above, the received codeword y is not stored in the data path, and thus the sequence t (which is mathematically equivalent to y) is generated and used in the bucket counter calculations of Step 6b. Alternatively, bucket counters can be calculated using the sequences v and y, with Step 5 being canceled and t not being used.

In Step 6b above, LLR0 and LLR1 are generated as follows:

$$LLR 0 = round ( log ( \frac{B\_ 00}{B\_ 10} ) )$$

$$and$$

$$LLR 1 = round ( log ( \frac{B\_ 01}{B\_ 11} ) ) .$$

In some embodiments, for the example architectures illustrated in FIGS. 7 and 8, the checksum satisfying a condition corresponds to the checksum (or the partial checksum) being less than a predetermined threshold. Alternatively, the checksum satisfying a condition corresponds to the checksum (or the partial checksum) being less than a previous checksum (or partial checksum) value offset by a constant, i.e., the current checksum satisfies the condition when current_checksum<previous_checksum−constant. In some examples, the constant is a predetermined value. In other examples, it can be selected based on one or more checksum values, one or more LLR values, or one or more ones count values, or functions thereof.

In some embodiments, for the example architectures illustrated in FIGS. 7 and 8, the bucket counters can be configured to operate on only a portion of the codeword or sequence, e.g., only the first k bits of the sequences are evaluated to determine (and count) bit differences. In some examples, the first k bits represent the information (or systematic) bits of the codeword.

Embodiments of the disclosed technology are directed to an MSH decoder that learns the underlying NAND channel through the decoding process. The LLR metrics (e.g., LLR0 and LLR1) are estimated and tracked, and using the checksum to gate updating the LLR sequence further reduces the decoding latency. The described embodiments advantageously enhance the quality-of-service (QoS) of SSD devices and applications.

FIG. 10 is an example diagram illustrating a storage device that can be configured to implement the described embodiments. Referring to FIG. 10, a data storage device 1000 may include a flash memory 1010, a memory controller 1020, and an LDPC decoder 1030. The memory controller 1020 may control the flash memory 1010 and the LDPC decoder 1030 in response to control signals input from the outside of the data storage device 1000. In the data storage device 1000, the flash memory 1010 may be configured the same or substantially the same as a nonvolatile memory device. That is, the flash memory 1010 may read data from selected memory cells using different read voltages to output it to the memory controller 1020.

In some embodiments, the data storage device 1000 may be a memory card device, an SSD device, a multimedia card device, an SD card, a memory stick device, an HDD device, a hybrid drive device, or an USB flash device. For example, the data storage device 1000 may be a card which satisfies standards for user devices such as a digital camera, a personal computer, etc.

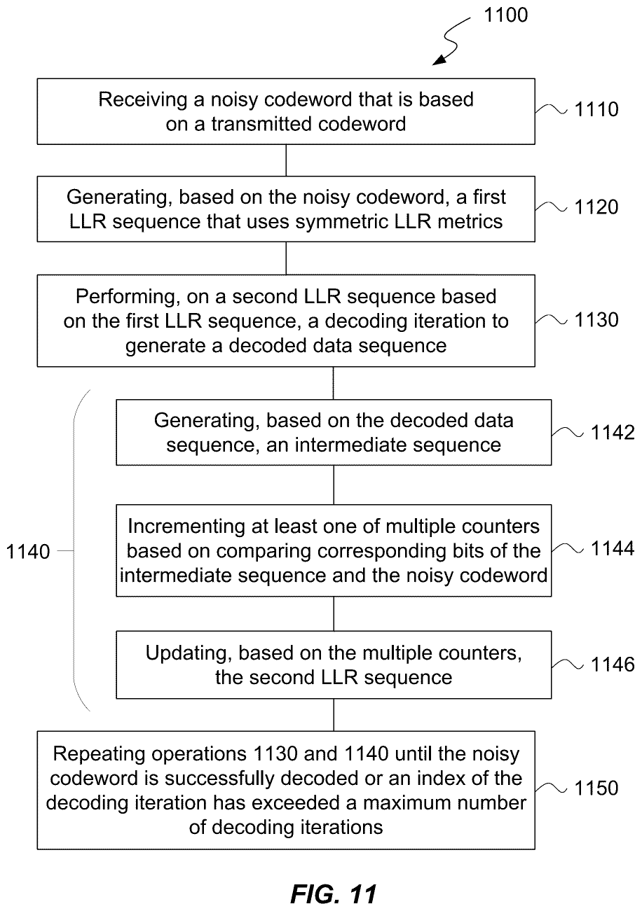

FIG. 11 illustrates a flowchart of an example method 1100 for improving the performance of a decoder in a memory device. The method 1100 includes, at operation 1110, receiving a noisy codeword that is based on a transmitted codeword. In some examples, the codeword is generated from an LDPC code. In other examples, the codeword is received from at least one memory cell of the memory device.

The method 1100 includes, at operation 1120, generating, based on the noisy codeword, a first log likelihood ratio (LLR) sequence that uses symmetric LLR metrics.

The method 1100 includes, at operation 1130, performing, on a second LLR sequence based on the first LLR sequence, a decoding iteration to generate a decoded data sequence.

Upon determining that a checksum of the decoded data sequence satisfies a condition indicative of the noisy codeword not being successfully decoded, the method 1100 includes operation 1140, which includes operations 1142 through 1146.

The method 1100 includes, at operation 1142, generating, based on the decoded data sequence, an intermediate sequence.

The method 1100 includes, at operation 1144, incrementing at least one of multiple counters based on comparing corresponding bits of the intermediate sequence and the noisy codeword. In this example, the multiple counters include a first counter (B_00), a second counter (B_01), a third counter (B_10), and a fourth counter (B_11).

The method 1100 includes, at operation 1146, updating, based on the multiple counters (e.g., B_00, B_01, B_10 and B_11), the second LLR sequence.

The method 1100 includes, at operation 1150, repeating operations 1130 and 1140 until the noisy codeword is successfully decoded or an index of the decoding iteration has exceeded a maximum number of decoding iterations.

In some embodiments, comparing the corresponding bits is performed for a first k bits of the noisy codeword and the intermediate sequence (with k being a positive integer), and (i) the first counter (B_00) is incremented by one when the corresponding bits of the intermediate sequence and the noisy codeword are both zero, (ii) the second counter (B_01) is incremented by one when the corresponding bits of the intermediate sequence and the noisy codeword are zero and one, respectively, (iii) the third counter (B_10) is incremented by one when the corresponding bits of the intermediate sequence and the noisy codeword are one and zero, respectively, and (iv) the fourth counter (B_11) is incremented by one when the corresponding bits of the intermediate sequence and the noisy codeword are both one.

In some embodiments, updating the second LLR sequence includes computing a first LLR metric (LLR0) as round(log (B_00/B_10)), computing a second LLR metric (LLR1) as round(log (B_01/B_11)), and replacing a magnitude of each LLR in the second LLR sequence with LLR0 or LLR1. Herein, round(·) is a function returning a closest integer to an input argument and log (·) is a function returning a natural logarithm of the input argument.

In some embodiments, the first k bits comprise all bits in the noisy codeword. In other embodiments, the first k bits correspond to the information (or systematic) bits of the codeword.

In some embodiments, the checksum of the decoded data sequence satisfying the condition comprises (a) a current checksum being less than a predetermined threshold or (b) the current checksum being less than a difference between a previous checksum and a constant.

In some embodiments, the transmitted codeword is scrambled prior to being written to the at least one memory cell, and generating the intermediate sequence includes computing an element-wise exclusive OR (XOR) between the decoded data sequence and a scrambling sequence. In some examples, the second LLR sequence comprises the element-wise XOR between the first LLR sequence and the scrambling sequence (e.g., as shown in the architecture in FIG. 7). In other examples, the first LLR sequence comprises the element-wise XOR between the noisy codeword and the scrambling sequence, and the second LLR sequence is the first LLR sequence (e.g., as shown in the architecture in FIG. 8). In other embodiments, the transmitted codeword (e.g., LDPC encoded data) is directly written to the at least one memory cell (without being scrambled), and the intermediate sequence is identical to the decoded data sequence.

In some embodiments, the memory device comprises a quad-level cell (QLC).

Implementations of the subject matter and the functional operations described in this patent document can be implemented in various systems, digital electronic circuitry, or in computer software, firmware, or hardware, including the structures disclosed in this specification and their structural equivalents, or in combinations of one or more of them. Implementations of the subject matter described in this specification can be implemented as one or more computer program products, i.e., one or more modules of computer program instructions encoded on a tangible and non-transitory computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more of them. The term “data processing unit” or “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. Processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, flash memory devices. The processor and the memory can be supplemented by, or incorporated in, special purpose logic circuitry.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

What is claimed is:

1. A method of improving a performance of a decoder in a memory device, comprising:
(a) receiving, from at least one memory cell of the memory device, a noisy codeword that is based on a transmitted codeword generated from a low-density parity-check (LDPC) code;
(b) generating, based on the noisy codeword, a first log likelihood ratio (LLR) sequence that uses symmetric LLR metrics;
(c) performing, on a second LLR sequence, a decoding iteration to generate a decoded data sequence, wherein the second LLR sequence is based on the first LLR sequence;
upon determining that a checksum of the decoded data sequence satisfies a condition indicative of the noisy codeword not being successfully decoded,
(d) generating, based on the decoded data sequence, an intermediate sequence;
(e) incrementing at least one of a first counter (B_00), a second counter (B_01), a third counter (B_10), or a fourth counter (B_11) based on comparing corresponding bits of the intermediate sequence and the noisy codeword; and
(f) updating, based on the first counter, the second counter, the third counter, and the fourth counter, the second LLR sequence; and
(g) repeating operations (c) through (f) until the noisy codeword is successfully decoded or an index of the decoding iteration has exceeded a maximum number of decoding iterations.

2. The method of claim 1, wherein comparing the corresponding bits is performed for a first k bits of the noisy codeword and the intermediate sequence, wherein k is an integer, and wherein:
the first counter (B_00) is incremented by one when the corresponding bits of the intermediate sequence and the noisy codeword are both zero,
the second counter (B_01) is incremented by one when the corresponding bits of the intermediate sequence and the noisy codeword are zero and one, respectively,
the third counter (B_10) is incremented by one when the corresponding bits of the intermediate sequence and the noisy codeword are one and zero, respectively, and
the fourth counter (B_11) is incremented by one when the corresponding bits of the intermediate sequence and the noisy codeword are both one.

3. The method of claim 2, wherein updating the second LLR sequence comprises:
computing a first LLR metric (LLR0) as round(log (B_00/B_10));
computing a second LLR metric (LLR1) as round(log (B_01/B_11)); and
replacing a magnitude of each LLR in the second LLR sequence with LLR0 or LLR1,
wherein round(·) is a function returning a closest integer to an input argument and log (·) is a function returning a natural logarithm of the input argument.

4. The method of claim 2, wherein the first k bits comprise all bits in the noisy codeword.

5. The method of claim 1, wherein the checksum of the decoded data sequence satisfying the condition comprises (a) a current checksum being less than a predetermined threshold or (b) the current checksum being less than a difference between a previous checksum and a constant.

6. The method of claim 1, wherein the transmitted codeword is scrambled prior to being written to the at least one memory cell, and wherein generating the intermediate sequence comprises:
computing an element-wise exclusive OR (XOR) between the decoded data sequence and a scrambling sequence.

7. The method of claim 6, wherein the second LLR sequence comprises the element-wise XOR between the first LLR sequence and the scrambling sequence.

8. The method of claim 6, wherein the first LLR sequence comprises the element-wise XOR between the noisy codeword and the scrambling sequence.

9. The method of claim 8, wherein the second LLR sequence is the first LLR sequence.

10. The method of claim 1, wherein the memory device comprises a quad-level cell (QLC).

11. A system for improving a performance of a decoder in a memory device, comprising:
one or more processors and a memory including instructions stored thereupon, wherein the instructions upon execution by the one or more processors cause the one or more processors to:
(a) receive, from at least one memory cell of the memory device, a noisy codeword that is based on a transmitted codeword generated from a low-density parity-check (LDPC) code;
(b) generate, based on the noisy codeword, a first log likelihood ratio (LLR) sequence that uses symmetric LLR metrics;
(c) perform, on a second LLR sequence, a decoding iteration to generate a decoded data sequence, wherein the second LLR sequence is based on the first LLR sequence;
upon determining that a checksum of the decoded data sequence satisfies a condition indicative of the noisy codeword not being successfully decoded,
(d) generate, based on the decoded data sequence, an intermediate sequence;
(e) increment at least one of a first counter (B_00), a second counter (B_01), a third counter (B_10), or a fourth counter (B_11) based on comparing corresponding bits of the intermediate sequence and the noisy codeword; and
(f) update, based on the first counter, the second counter, the third counter, and the fourth counter, the second LLR sequence; and
(g) repeat operations (c) through (f) until the noisy codeword is successfully decoded or an index of the decoding iteration has exceeded a maximum number of decoding iterations.

12. The system of claim 11, wherein comparing the corresponding bits is performed for a first k bits of the noisy codeword and the intermediate sequence, wherein k is an integer, and wherein:
the first counter (B_00) is incremented by one when the corresponding bits of the intermediate sequence and the noisy codeword are both zero,
the second counter (B_01) is incremented by one when the corresponding bits of the intermediate sequence and the noisy codeword are zero and one, respectively,
the third counter (B_10) is incremented by one when the corresponding bits of the intermediate sequence and the noisy codeword are one and zero, respectively, and
the fourth counter (B_11) is incremented by one when the corresponding bits of the intermediate sequence and the noisy codeword are both one.

13. The system of claim 12, wherein the instructions upon execution by the one or more processors cause the one or more processors, as part of updating the second LLR sequence, to:
compute a first LLR metric (LLR0) as round(log (B_00/B_10));
compute a second LLR metric (LLR1) as round(log (B_01/B_11)); and
replace a magnitude of each LLR in the second LLR sequence with LLR0 or LLR1,
wherein round(·) is a function returning a closest integer to an input argument and log (·) is a function returning a natural logarithm of the input argument.

14. The system of claim 11, wherein the checksum of the decoded data sequence satisfying the condition comprises (a) a current checksum being less than a predetermined threshold or (b) the current checksum being less than a difference between a previous checksum and a constant.

15. The system of claim 11, wherein the transmitted codeword is scrambled prior to being written to the at least one memory cell, and wherein the instructions upon execution by the one or more processors cause the one or more processors, as part of generating the intermediate sequence, to:
compute an element-wise exclusive OR (XOR) between the decoded data sequence and a scrambling sequence.

16. A non-transitory computer-readable storage medium having instructions stored thereupon for improving a performance of a decoder in a memory device, comprising:
(a) instructions for receiving, from at least one memory cell of the memory device, a noisy codeword that is based on a transmitted codeword generated from a low-density parity-check (LDPC) code;
(b) instructions for generating, based on the noisy codeword, a first log likelihood ratio (LLR) sequence that uses symmetric LLR metrics;
(c) instructions for performing, on a second LLR sequence, a decoding iteration to generate a decoded data sequence, wherein the second LLR sequence is based on the first LLR sequence;
upon determining that a checksum of the decoded data sequence satisfies a condition indicative of the noisy codeword not being successfully decoded,
(d) instructions for generating, based on the decoded data sequence, an intermediate sequence;
(e) instructions for incrementing at least one of a first counter (B_00), a second counter (B_01), a third counter (B_10), or a fourth counter (B_11) based on comparing corresponding bits of the intermediate sequence and the noisy codeword; and
(f) instructions for updating, based on the first counter, the second counter, the third counter, and the fourth counter, the second LLR sequence; and
(g) instructions for repeating operations (c) through (f) until the noisy codeword is successfully decoded or an index of the decoding iteration has exceeded a maximum number of decoding iterations.

17. The non-transitory computer-readable storage medium of claim 16, wherein comparing the corresponding bits is performed for a first k bits of the noisy codeword and the intermediate sequence, wherein k is an integer, and wherein:
the first counter (B_00) is incremented by one when the corresponding bits of the intermediate sequence and the noisy codeword are both zero,
the second counter (B_01) is incremented by one when the corresponding bits of the intermediate sequence and the noisy codeword are zero and one, respectively,
the third counter (B_10) is incremented by one when the corresponding bits of the intermediate sequence and the noisy codeword are one and zero, respectively, and
the fourth counter (B_11) is incremented by one when the corresponding bits of the intermediate sequence and the noisy codeword are both one.

18. The non-transitory computer-readable storage medium of claim 17, wherein the instructions for updating the second LLR sequence comprise:
instructions for computing a first LLR metric (LLR0) as round(log (B_00/B_10));
instructions for computing a second LLR metric (LLR1) as round(log (B_01/B_11)); and
instructions for replacing a magnitude of each LLR in the second LLR sequence with LLR0 or LLR1,
wherein round(·) is a function returning a closest integer to an input argument and log (·) is a function returning a natural logarithm of the input argument.

19. The non-transitory computer-readable storage medium of claim 16, wherein the checksum of the decoded data sequence satisfying the condition comprises (a) a current checksum being less than a predetermined threshold or (b) the current checksum being less than a difference between a previous checksum and a constant.

20. The non-transitory computer-readable storage medium of claim 16, wherein the transmitted codeword is scrambled prior to being written to the at least one memory cell, and wherein the instructions for generating the intermediate sequence comprise:
instructions for computing an element-wise exclusive OR (XOR) between the decoded data sequence and a scrambling sequence.
